(19) United States
(12) Patent Application Publication
(10) Pub. No.: US 2004/0029341 A1
(43) Pub. Date: Feb. 12, 2004

(54) Gap diode device

(76) Inventors: Isaiah Watas Cox, London (GB); Leri Tsakadze, Tbilisi (GE); Avto Tavkhelidze, Tibilisi (GE)

Correspondence Address: Borealis Technical Limited, 23545 NW Skyline Blvd, North Plains, OR, 97133-9204, US

(21) Appl. No.: 10/632,781

(22) Filed: Aug. 1, 2003

Related U.S. Application Data
(60) Provisional application No. 60/400,959, filed on Aug. 1, 2002.

(51) Int. Cl. H01L 21/20; H01L 21/336; H01L 21/8234

(52) U.S. Cl. 438/237; 438/141; 438/979

(57) ABSTRACT

Gap diode devices having improved operating stability and enhanced electrode lifetimes are disclosed. The devices contain a material in vapor form between the electrodes, which reduces evaporative losses from the electrode surfaces.

### CROSS-REFERENCE TO RELATED APPLICATIONS

This application claims the benefit of U.S. Provisional Application No. 60/400,959, filed Aug. 1, 2002.

### BACKGROUND OF THE INVENTION

The present invention relates to gap diode devices, and more particularly, to reducing surface deformations in gap diode electrodes. “Gap Diode” is defined as a diode in which the insulating layer between the electrodes is not a continuous solid layer, but has a gap between the solid electrodes.

Having smooth flat closely-spaced electrodes is a desirable feature for gap diodes, such as those used in thermionic converters, vacuum diode heat pumps, tunneling converters and the like. For tunneling diode devices especially, the separation of the electrodes is necessarily very small so that electrons may tunnel from an emitter electrode to a collector electrode. Performance of such a device is very dependent on maintaining the gap within a defined range. Thus factors that affect the magnitude of the gap, either locally or globally, are very important.

One such factor is evaporation. This is loss of atoms or molecules that form part of the surface of the electrodes. This kind of evaporation can occur at virtually any temperature, although the evaporation rate is highly dependent on such factors as material type, temperature and the partial pressure in the gap.

This kind of evaporation can also limit emitter lifetime, as active material is lost from the surface of the emitter.

There remains a need therefore for reducing the evaporation of a gap diode electrode material from its surface.

### BRIEF SUMMARY OF THE INVENTION

The present invention relates to a method for reducing surface deformation of gap diode electrodes, and comprises the step of increasing the vapor pressure of a material in a space between the electrodes to a point where evaporative losses from the electrode surfaces are reduced, whereby surface deformation will be reduced.

In a particularly preferred aspect, the present invention relates to a method for reducing surface deformation of closely spaced topologically-matched electrodes of a gap diode device, and comprises the step of increasing the vapor pressure of a material in a space between the electrodes to a point where evaporative losses from the electrode surfaces are reduced, whereby surface deformation will be reduced.

The invention also relates to methods for reducing evaporation from electrode surfaces by including a material in vapor form in the space between them.

In either aspect, the material may be a metal, a mixture of metals or some other material able to inhibit evaporation.

### BRIEF DESCRIPTION OF THE SEVERAL VIEWS OF THE DRAWING

For a more complete understanding of the present invention and the technical advantages thereof, reference is made to the following description taken with the accompanying drawings, in which:

FIG. 1 shows evaporation of material from a surface, leading to surface deformation

FIG. 2 shows the presence of a vapor material above a surface, leading to a reduction in the evaporation of material from the surface, leading to reduction in surface deformation.

FIG. 3 shows in schematic form a method for producing pairs of electrodes having substantially smooth surfaces in which any topographical features in one are matched in the other, and which includes a vaporizable material.

FIG. 4 shows in schematic form a method for fabricating a gap diode device having closely-spaced electrodes having substantially smooth surfaces in which any topographical features in one are matched in the other, and which includes a vaporizable material.

FIG. 5 shows a tubular actuating element utilized in the construction of gap diodes.

FIG. 6 shows a composite electrode utilized in the construction of gap diodes, and having a layer of a vaporizable material.

FIG. 7 shows in schematic form a method for fabricating a gap diode device having closely-spaced electrodes having substantially smooth surfaces in which any topographical features in one are matched in the other, and which includes a vaporizable material.

### DETAILED DESCRIPTION OF THE INVENTION

Evaporation from metal surfaces has been well studied. From these data, it is possible to estimate the evaporation rates from gap diode electrode surfaces.

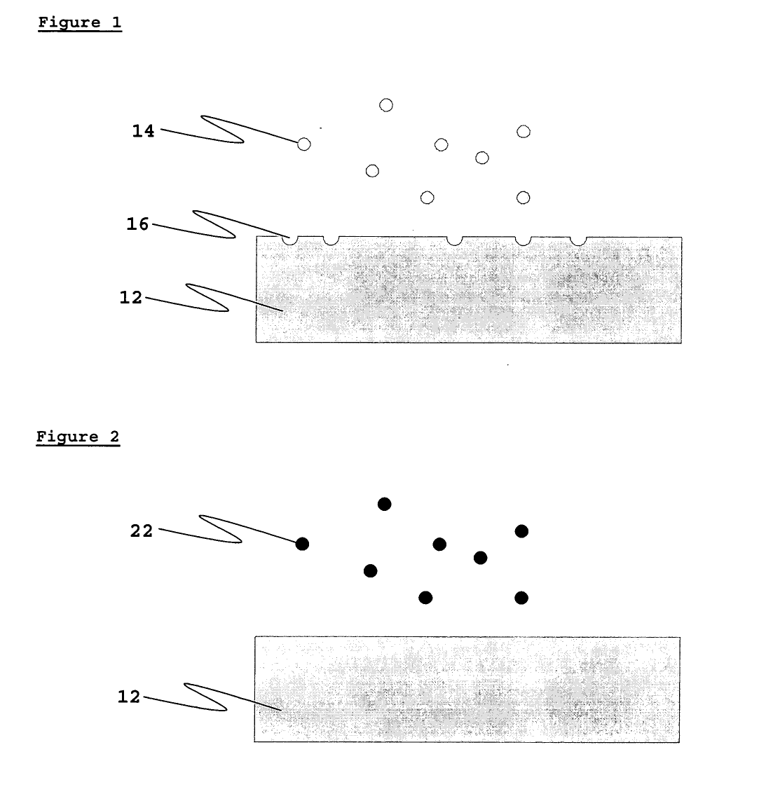

The effect of this kind of surface evaporation is shown diagrammatically in FIG. 1, in which atoms 14 leave an electrode surface 12 of a tunneling diode device, resulting in a deformation of the surface, or a ‘hole’, 16.

Referring now to FIG. 2, which shows atoms 22 of a material in vapor form above the electrode surface, the vapor pressure exerted by these atoms reduces the tendency of atoms 14 from the surface to evaporate, and prevents deformation of the surface.

) In a preferred embodiment, the material used is a metal, and most preferably, it is cesium. It is expected that the use of a cesium vapor in the gap will reduce the evaporation rate by a factor of 200-500. There are a number of ways in which a material in vapor form may be introduced into the space between the electrodes. The vapor may be introduced after the diode device has been assembled. For example, the space between the electrodes may be evacuated, and then the vapor introduced. Alternatively, the vapor may be introduced during the manufacturing process.

In the foregoing, it has been indicated that metal vapor may be utilized. In many instances, the metal may not be able exist as a vapor except under operating conditions, when the temperature is sufficiently high to vaporize it. Under these conditions, the metal itself may be introduced as the device is assembled, or as an electrode pair is manufactured.

The following exemplifies methods for making gap diode devices in which the space between the electrodes is filled with a metal vapor; in these examples the vapor is cesium vapor, but other metal vapors, and other materials in vapor form could be used also. These examples are not intended to limit the scope of the invention but as merely providing illustrations of some of the presently preferred embodiments of this invention.

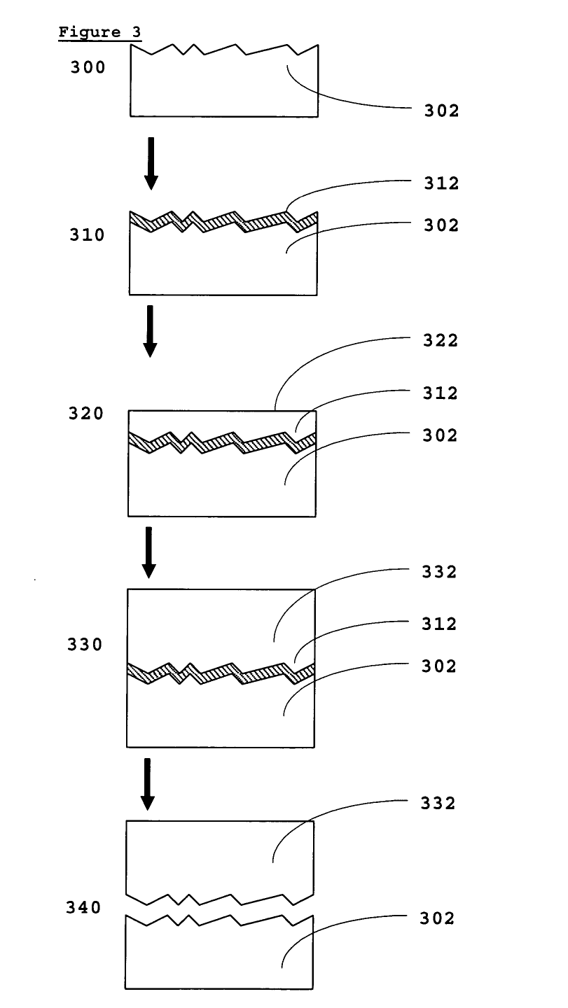

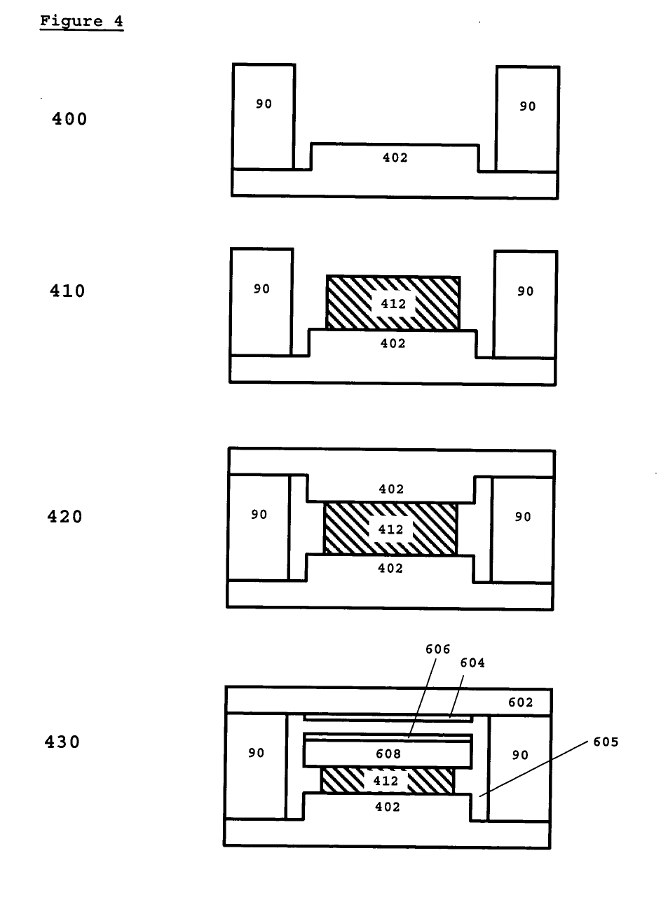

One approach for making gap diodes in which the space between the electrodes contains metal vapor is illustrated in FIG. 3, which in schematic form describes a method for producing pairs of electrodes having substantially smooth surfaces in which any topographical features in one are matched in the other.

The method involves a first step 300 in which a polished monocrystal of material 302 is provided. This forms one of the pair of electrodes. Material 302 may also be polished tungsten, or other materials.

In a step 310 a thin layer of a metal 312, preferably Zinc, Lead, Cadmium, Thallium, Bismuth, Polonium, Tin, Selenium, Lithium, Indium, Sodium, Potassium, Gallium, or Cesium is deposited onto the surface of the material 302. Any metal or material that has a significant vapor pressure under the operating conditions of the gap diode may be used This layer, the sacrificial layer, is sufficiently thin so that the shape of the polished surface 302 is repeated with high accuracy.

A thin layer of a third material is deposited on layer 312 in a step 320, and in a step 330 it is thickened using electrochemical growth to form second electrode 332. This forms the second electrode.

In a step 340 the composite formed in steps 300 to 330 is heated, which causes the sacrificial layer 312 to begin to evaporate before the melting temperature is reached. Considerable vapor pressure is developed inside the sandwich. For example, with Cadmium, the vapor pressure at 350° C. is enough to open the sandwich. Further, with cesium, cesium has a melting temperature of about 30 C and so the sandwich will open easily. For example heating the composite to 35 C will open it without introducing appreciable tension in the electrodes. The cesium is retained between the electrodes as a vapor by a housing (not shown).

Another approach for making gap diodes in which the space between the electrodes contains metal vapor is illustrated in FIG. 4, which depicts a schematic process for making such devices.

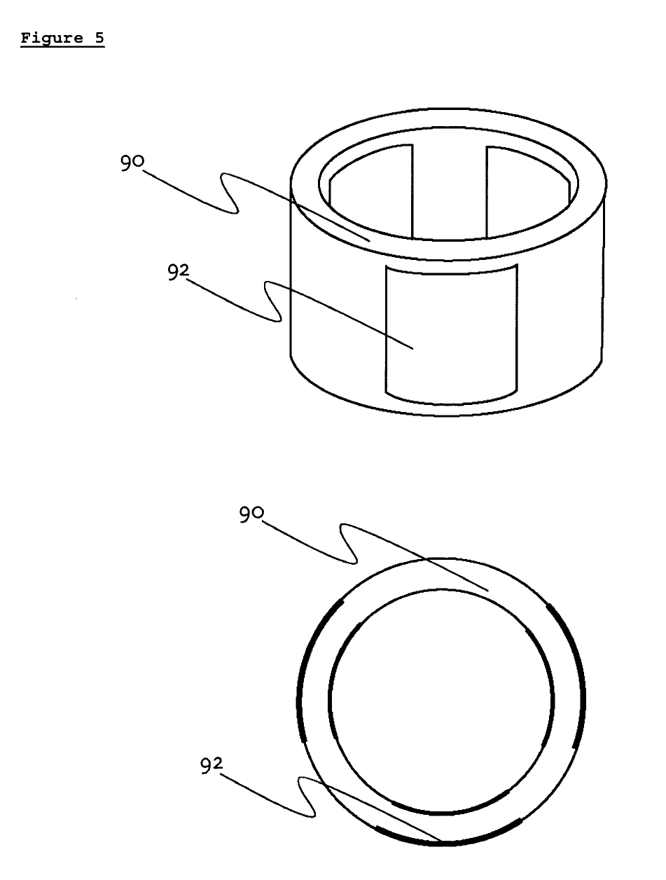

In step 400 a first composite 402 is brought into contact with a polished end of a quartz tube 90 of the sort shown in FIG. 5; here, a tubular actuating element 90 has pairs of electrodes 92 disposed on its inner and outer surfaces for controlling the dimensions of the tubular element.

FIG. 5 shows three such electrode pairs; fewer or more of such pairs may be present to control the dimensions of the tubular element. FIG. 5 shows electrodes disposed substantially over the length of the tube; electrodes may also be disposed over smaller areas of the tube to allow more or less local control of the dimensions of the tube. A variety of techniques may be used to introduce the pairs of electrodes onto the tubular element; by way of example only, and not to limit the scope of the invention, they may introduced by vacuum deposition, or by attaching a thin film using MEMS techniques. In a preferred embodiment, the actuating element is a piezo-electric actuator. In a particularly preferred embodiment, the actuator comprises quartz. The crystal orientation of the tube is preferably substantially constant, and may be aligned either parallel to, or perpendicular to the axis of the tube. Although FIG. 5 shows an actuator tube having an approximately circular cross-section, it is to be understood that other geometries are included within the scope of the invention. An electric field may be applied to actuating element 90. An advantage of such a tubular actuator is that it serves both as actuator and as housing simultaneously. The housing provides mechanical strength together with the ability to retain cesium or other metal vapor in the device.

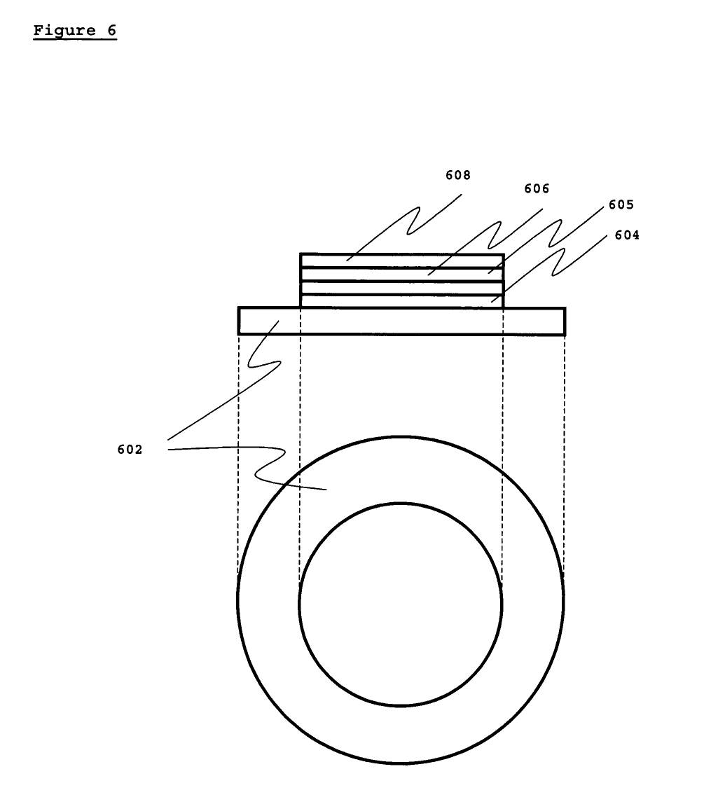

Composite 402 may be the composite shown in step 130 of FIG. 3, or is more preferably the composite depicted in FIG. 6, in which a layer of titanium 604 is deposited on substrate 602, and a layer of cesium 605 is deposited on the layer of titanium. The cesium layer has a thickness in the 2-20 nm range. A layer of silver 606 is further deposited on the layer of cesium. A further layer of copper 608 is grown electrochemically on the layer of silver. To avoid oxidization of the cesium, during the process of electrochemical growth of Cu the edge of the film is protected against contact with atmosphere and the silver paste or liquid metal. Most preferably substrate 602 is a silicon wafer, and is polished at least around its periphery where it is in contact with tube 90.

In step 410, an electrically conducting paste 412, preferably silver paste, is applied to the upper surface of the lower composite, as shown. Where the composite is the composite depicted in FIG. 6, the conducting paste is applied to the electrochemically grown layer of copper 608.

In step 420, the polished silicon periphery of the upper composite 402 is contacted with the other polished end of the quartz tube 90; at the same time, the electrically-conducting paste, preferably silver paste or liquid metal, contacts the upper composite as shown. High pressure is applied to this assemblage, which accelerates the chemical reaction between the polished silicon periphery of the composites and the polished ends of the quartz tube, bonding the polished surfaces to form the assemblage depicted in step 420.

In step 430, the assemblage is heated, which causes the composite to open as shown, forming two electrodes, 604 and 606. Cesium has a melting temperature of about 30 C and so the sandwich will open very easily. Cesium layer 605 now forms a vapor within the housing as shown. For example heating the composite to 35 C will open it without introducing appreciable tension in the electrodes. In FIG. 4, upper composite 402 does not have the cesium layer, and so does not ‘open’ like the lower composite.

In a further embodiment, composite 402 shown in FIG. 4 may comprise Molybdenum of the same shape and dimensions as the upper composite. This metal has a similar thermal expansion coefficient as quartz and can be bonded to quartz.

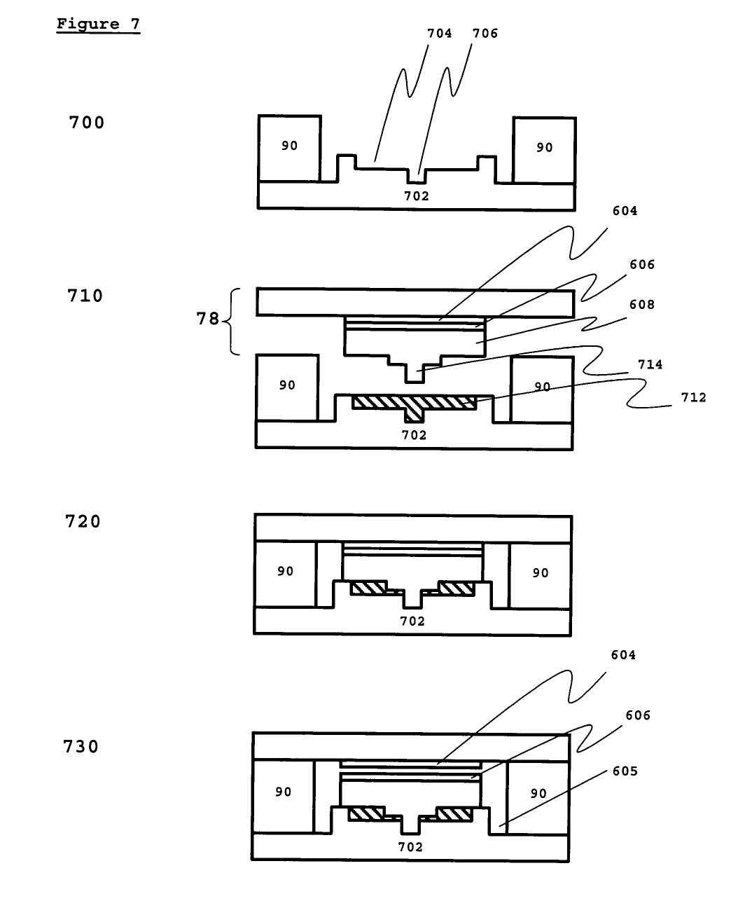

Referring now to FIG. 7, which depicts a further schematic process for making gap diodes in which the space between the electrodes contains metal vapor, in step 700 a first substrate 702 is brought into contact with a polished end of a quartz tube 90 of the sort shown in FIG. 7. Substrate 702 is any material which may be bonded to quartz, and which has a similar thermal expansion coefficient to quartz. Preferably substrate 702 is molybdenum, or silicon doped to render at least a portion of it electrically conductive. Substrate 702 has a depression 704 across part of its surface. Substrate 702 also has a locating hole 706 in its surface.

In step 710, liquid metal 712, is introduced into depression 702. The liquid metal is a metal having a low vapor pressure, and which is liquid under the conditions of operation of the device. The low vapor pressure ensures that the vapor from the liquid does not degrade the vacuum within the finished device. Preferably the liquid metal is a mixture of Indium and Gallium. Composite 502 is positioned so that alignment pin 714 is positioned above locating hole 706. Composite 502 is preferably the composite depicted in FIG. 6, in which a layer of titanium 604 is deposited on substrate 602, and a layer of cesium 605 is deposited on the layer of titanium. The cesium layer has a thickness in the 2-20 nm range. A layer of silver 606 is further deposited on the layer of cesium. A further layer of copper 608 is grown electrochemically on the layer of silver. To avoid oxidization of the cesium, during the process of electrochemical growth of Cu the edge of the film is protected against contact with atmosphere and the silver paste or liquid metal. Alignment pin 714, which is pre-machined, is placed on the composite near the end of the electrolytic growth phase; this results in its attachment to the layer of copper 608. The diameter of the alignment pin is the same as the diameter of the locating hole.

In step 720, the polished silicon periphery of the composite 78 is contacted with the other polished end of a quartz tube 90 of the type shown in FIG. 5; at the same time, the attachment pin seats in locating hole. During this step, substrate 702 is heated so that locating hole expands; when the assemblage is subsequently cooled, there is a tight fit between the alignment pin and the locating hole. High pressure is applied to this assemblage, which accelerates the chemical reaction between the polished silicon periphery of the composites and the polished ends of the quartz tube, bonding the polished surfaces to form the assemblage depicted in step 720.

In step 730, the assemblage is heated, and a signal applied to the quartz tube to cause the composite to open as shown, forming two electrodes, 604 and 606. Cesium has a melting temperature of about 30 C and so the sandwich will open very easily. For example heating the composite to 35 C will open it without introducing appreciable tension in the electrodes, so that when the electrode composite/quartz tube shown in FIG. 9 is heated, the electrode composite opens as shown. Cesium layer 605 now forms a vapor within the housing as shown. During the opening process, the tight fit between the alignment pin and the locating hole ensures that the electrodes 604 and 606 do not slide relative to one another.

Although the above specification contains many specificities, these should not be construed as limiting the scope of the invention but as merely providing illustrations of some of the presently preferred embodiments of this invention.

1. A method for reducing surface deformation of gap diode electrodes comprising the step of increasing a vapor pressure of a material in a space between said electrodes, thereby reducing evaporative losses from said surface, whereby surface deformation will be reduced.

2. The method of claim 1 wherein said material comprises a material that exerts a significant vapor pressure at an operating temperature of said gap diode.

3. The method of claim 1 wherein said material comprises a metal.

4. The method of claim 3 wherein said metal is chosen from the group consisting of: Zinc, Lead, Cadmium, Thallium, Bismuth, Tin, Selenium, Lithium, Indium, Sodium, Potassium, Gallium, and Cesium.

5. The method of claim 3 wherein said metal comprises Cesium.

6. The method of claim 1 in which one or both of said electrodes comprise said material in solid form, and wherein said step of increasing a vapor pressure comprises the step of increasing an operating temperature of said gap diode to a value at which a vapor pressure of said material is sufficient to prevent said evaporative losses.

7. The method of claim 6 wherein said material comprises a metal.

8. The method of claim 7 wherein said metal is chosen from the group consisting of: Zinc, Lead, Cadmium, Thallium, Bismuth, Tin, Selenium, Lithium, Indium, Sodium, Potassium, Gallium, and Cesium.

9. The method of claim 7 wherein said material comprises Cesium and wherein said step of increasing an operating temperature comprises the step of increasing an operating temperature to a temperature greater than 30° C.

10. The method of claim 7 wherein said material comprises Cadmium and wherein said step of increasing an operating temperature comprises the step of increasing an operating temperature to a temperature greater than 350° C.

11. A method for reducing evaporative losses of electrode material from one or both electrodes of a gap diode device comprising the step of introducing a further material in vapor form into a space between said electrodes, whereby a vapor pressure of said further material reduces said evaporative losses.

12. The method of claim 11 wherein said material comprises a material that exerts a significant vapor pressure at an operating temperature of said gap diode.

13. The method of claim 11 wherein said material comprises a metal.

14. The method of claim 13 wherein said metal is chosen from the group consisting of: Zinc, Lead, Cadmium, Thallium, Bismuth, Tin, Selenium, Lithium, Indium, Sodium, Potassium, Gallium, and Cesium.

15. The method of claim 13 wherein said metal comprises Cesium.

16. The method of claim 11 in which one or both of said electrodes comprise said material in solid form, and wherein said step of introducing a further material in vapor form comprises the step of increasing an operating temperature of said gap diode to a value at which a vapor pressure of said material is sufficient to prevent said evaporative losses.

17. The method of claim 16 wherein said metal is chosen from the group consisting of: Zinc, Lead, Cadmium, Thallium, Bismuth, Tin, Selenium, Lithium, Indium, Sodium, Potassium, Gallium, and Cesium.

18. The method of claim 16 wherein said material comprises Cesium and wherein said step of increasing an operating temperature comprises the step of increasing an operating temperature to a temperature greater than 30° C.

19. The method of claim 16 wherein said material comprises Cadmium and wherein said step of increasing an operating temperature comprises the step of increasing an operating temperature to a temperature greater than 350° C.

20. The method of claim 1 wherein said gap diode is used for tunnel emission of electrons.

21. The method of claim 1 wherein said gap diode is used for thermionic emission of electrons.

22. The method of claim 1 wherein said gap diode is used for field emission of electrons.

23. The method of claim 11 wherein said gap diode is used for tunnel emission of electrons.

24. The method of claim 11 wherein said gap diode is used for thermionic emission of electrons.

25. The method of claim 11 wherein said gap diode is used for field emission of electrons.
